(19) United States
(12) Patent Application Publication
(10) Pub. No.: US 2014/0146501 A1
(43) Pub. Date: May 29, 2014

(54) ELECTRONIC DEVICE IN PLASTIC

(71) Applicants: David Thiel, Nathan (AU); Neeli Madhusudanrao, Nathan (AU)

(72) Inventors: David Thiel, Nathan (AU); Neeli Madhusudanrao, Nathan (AU)

(73) Assignee: Griffith University, Nathan (AU)

(21) Appl. No.: 13/881,615

(22) PCT Filed: Oct. 7, 2011
(86) PCT No.: PCT/AU11/01288

§ 371 Date: Jun. 18, 2013

(30) Foreign Application Priority Data
Oct. 29, 2010 (AU) 2010904840

(51) Int. Cl. H05K 1/02; H05K 3/00; H05K 1/18

(52) U.S. Cl. CPC H05K 1/0204; H05K 1/185; H05K 3/0064
USPC 361/762; 156/308.2

(57) ABSTRACT

The invention concerns a method for forming an electronic device in plastic. The method for forming an electronic device in plastic comprises: (a) placing electronic components (220, 215) in recesses (210, 215) in a thermoplastic substrate (200); (b) depositing (135) an electronic circuit (230) over the electronic components (220, 225), or onto a thermoplastic sheet (240); and (c) bonding (160) the thermoplastic substrate (200) with the thermoplastic sheet (240) in a thermal bonding process to seal the electronic components (220, 215) and the electronic circuit (230) between the thermoplastic substrate (200) and the thermoplastic sheet (240), wherein the method further comprises providing a thermally conductive layer (250) on the thermoplastic sheet (240) and/or substrate (200) such that heat applied during the thermal bonding process is distributed uniformly across the thermoplastic sheet (240) and/or substrate (200) to facilitate bonding of the thermoplastic sheet (240) and substrate (200). In another aspect, the invention concerns an electronic device formed according to the method. It is an advantage that a more uniform heat distribution is achieved.

### CROSS-REFERENCE TO RELATED APPLICATION(S)

This application is related to International Application No. PCT/AU2006/000926 (Griffith University) and corresponding granted AU Patent Nos. 2006265765 and 2009233620, and claims priority from Australian Provisional application No 2010904840, the contents of which are herein incorporated by reference.

### TECHNICAL FIELD

The invention concerns a method for forming an electronic device in plastic. In another aspect, the invention concerns an electronic device formed according to the method.

### BACKGROUND OF THE ART

Electronic devices are traditionally made on a printed circuit board (PCB) where components such as chips are adhered to the substrate and then connected by metal tracks patterned on the substrate. For some applications, there is a need to encase the electronic components in a protective package.

PCT/AU2006/000926 discloses a method for forming an electronic device in plastic in which electronic components and circuitry are sealed and protected from environmental effects and mechanical impact. One or more electronic components are first placed in one or more recesses in a thermoplastic substrate. An electrical circuit is then deposited onto a thermoplastic sheet or over the one or more components. The thermoplastic sheet is bonded with the thermoplastic substrate to seal the electronic components and electrical circuitry between the thermoplastic sheet and substrate. Since this method is lead-free, it also reduces the cost of manufacture and environmental impact of the manufacturing process.

Any discussion of documents, acts, materials, devices, articles or the like which has been included in the present specification is not to be taken as an admission that any or all of these matters form part of the prior art base or were common general knowledge in the field relevant to the present invention as it existed before the priority date of each claim of this application.

### SUMMARY OF THE INVENTION

According to a first aspect, there is provided a method for forming an electronic device in plastic, comprising the steps of:
(a) placing electronic components in recesses in a thermoplastic substrate;
(b) depositing an electronic circuit over the electronic components, or onto a thermoplastic sheet; and
(c) bonding the thermoplastic substrate with the thermoplastic sheet in a thermal bonding process to seal the electronic components and the electronic circuit between the thermoplastic substrate and the thermoplastic sheet,
wherein the method further comprises providing a thermally conductive layer on the thermoplastic sheet and/or substrate such that heat applied during the thermal bonding process is distributed substantially uniformly across the thermoplastic sheet and/or substrate overlaid by the thermally conductive layer to facilitate bonding of the thermoplastic sheet and substrate.

It is an advantage of the method that a more uniform heat distribution is achieved across regions of the thermoplastic sheet or substrate overlaid by the thermally conductive layer. The use of the thermally conductive layer alleviates a problem observed with an electronic device formed using the method disclosed in PCT/AU2006/000926.

For example, if the electronic device comprises an electronic component having a larger thermal mass than that of other components, the larger thermal mass generally disrupts the temperature profile across the thermoplastic sheet or substrate to be bonded. In this case, the thermally conductive layer distributes heat more uniformly across the device and improves bonding of the thermoplastic sheet and substrate without significant plastic deformation in the vicinity of the electronic component with larger thermal mass. The thermally conductive layer also has a second function during normal operation of the electronic device to improve heat dissipation from the sealed electronic components and circuitry of the electronic device.

At least one of the electronic components may be a heat-sensitive component and the method may further comprise patterning the thermally conductive layer to reduce distribution of the heat applied during the thermal bonding process to the heat-sensitive component.

The thermally conductive layer may be thermally drivable with one or more of the sealed electronic components to regulate temperature to some or part of the electronic device.

The method may further comprise bonding the thermally conductive layer to the thermoplastic sheet or substrate, or both, either during or before step (c).

In another example, the layer may be both thermally and electrically conductive. In this case, the method may further comprise patterning the thermally and electrically conductive layer to function as an electromagnetic shield for the sealed electronic components and electronic circuit.

Advantageously, it is not necessary to package the formed electronic device in a separate shield to achieve electromagnetic compatibility. In this case, the thermally and electrically conducting layer is a multipurpose layer for uniform heat distribution during the thermal bonding process and for integrated heat dissipation and electromagnetic shielding during normal operation of the electronic device.

If the layer is both thermally and electrically conductive, the method may further comprise patterning the thermally and electrically conductive layer to function as an antenna that is inductively coupled to the sealed electronic circuit and/or one or more of the sealed electronic components.

Advantageously, it is not necessary to provide a separate antenna or component in the electronic device. In this case, the thermally and electrically conducting layer is a multipurpose layer for uniform heat distribution during the thermal bonding process. During normal operation of the electronic device, the thermally and electrically conductive layer serves to dissipate heat and as an antenna.

The method may further comprise patterning the layer to display textual or visual information.

The layer may comprise at least one of the following: aluminium foil, copper foil, printed silver, printed carbon, and conductive polymers.

According to a second aspect, there is provided an electronic device formed according to the method according to the first aspect.

### BRIEF DESCRIPTION OF DRAWINGS

Non-limiting example(s) of the method and electronic device(s) formed using the method will now be described with reference to the accompanying drawings, in which:

FIG. 1 is flowchart of steps of an exemplary method for forming an electronic device in plastic.

FIGS. 2(a) to 2(f) are a series of cross-sectional view of a first example of an electronic device during its formation.

FIGS. 3(a) to 3(f) are a series of cross-sectional view of part of a second example of an electronic device for selective thermal distribution.

FIG. 4(a) is a pictorial exploded view of the second example in FIG. 3(f).

FIG. 4(b) is a top view of the second example in FIG. 3(f).

FIGS. 5(a) to 5(c) are cross-sectional view, pictorial exploded view and top view of a third example of an electronic device for selective thermal distribution.

FIG. 6 is a cross-sectional view of a fourth example of an electronic device with a thermally drivable layer.

FIG. 7 is a top view of a fifth example of an electronic device with a thermally and electrically conductive layer also serving as an antenna.

### DETAILED DESCRIPTION

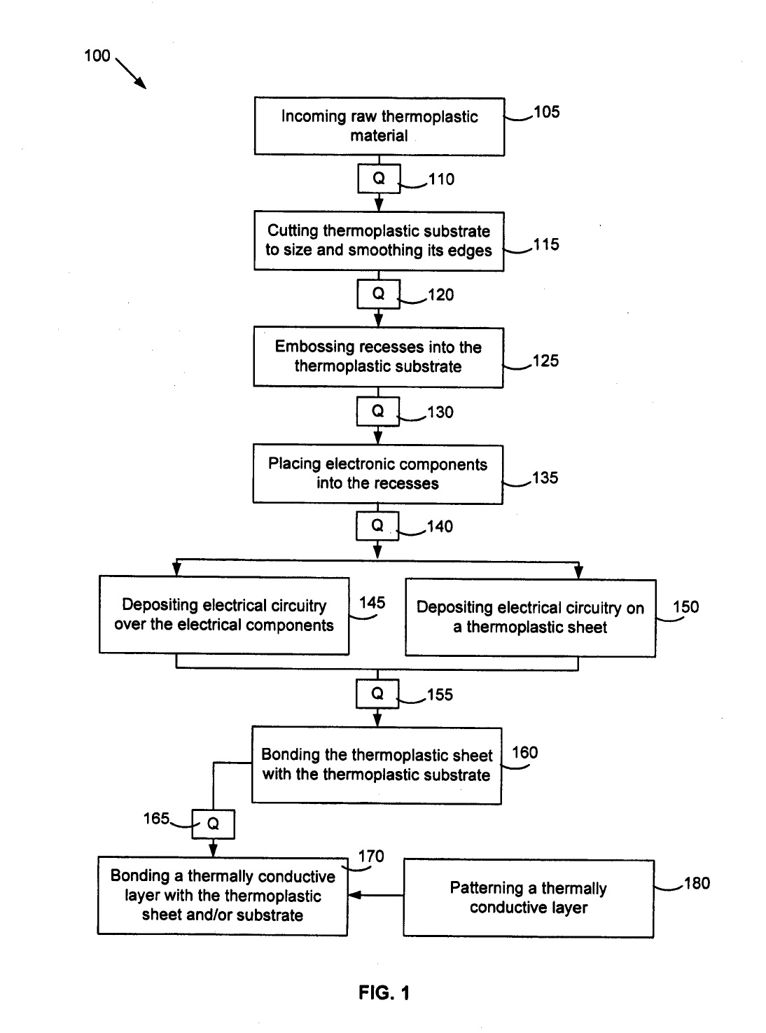

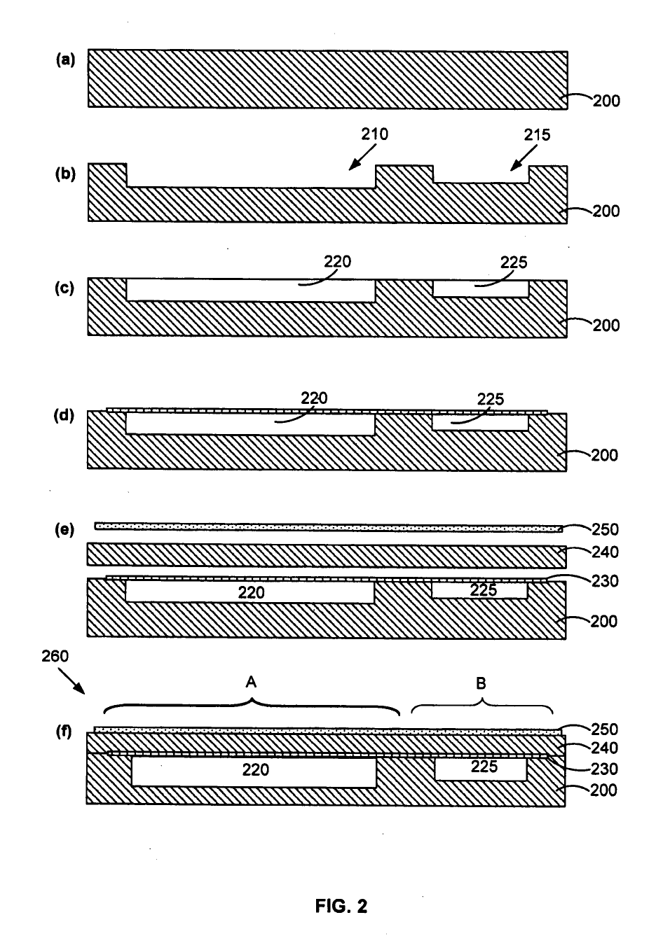

An exemplary method for forming an electronic device in plastic will now be explained with reference to the flowchart 100 in FIG. 1 along with various examples shown in FIG. 2 to FIG. 7. The steps are applicable to any suitable thermoplastic material such as polycarbonate by adapting the pressure, temperature and process time parameters.

First, an incoming thermoplastic substrate 200 is cut to size and its edges smoothed; see thermoplastic substrate may be polycarbonate sheet of 5 mm thickness. Quality checks are performed and the thermoplastic substrate 200 rejected if it fails the check; see steps 110 and 120.

Recesses 210, 215 that are shaped and sized to receive electronic components are then embossed into the thermoplastic substrate 200; see step 125 in FIG. 1 and FIG. 2(b). A quality check is then performed and the embossed thermoplastic substrate 200 rejected if it fails the check; see step 130. Alternatively, this step 125 may be omitted if the recesses 210, 215 are pre-formed, such as using injection moulding.

A hot embossing machine can be used for the embossing step. The machine preferably has a pneumatic press that is electrically regulated to control the applied pressure and top and bottom pressure plates embedded with heating elements. A temperature controller controls the plate temperature with thermocouples and limits the activation of the plates until the preset temperature settings are achieved.

Generally, a die is first aligned with the thermoplastic substrate 200, held together and placed on the bottom pressure plate. The top pressure plate is then contacted with the die and thermoplastic substrate 200, and preheats it to a predetermined temperature. Regulated pressure is then applied by the top pressure plate to emboss the recesses 210, 215 into the substrate 200. As shown in FIG. 2(b), the recesses 210, 215 may have different depths depending on the size of the electronic components used.

Next, electronic components 220, 225 are placed into the corresponding recesses 210, 215 using a pick and place machine; see step 135 in FIG. 1. Heat and pressure are applied to press the electronic components 220, 225 into the thermoplastic substrate 200 so that they stay flush to the upper surface as shown in FIG. 2(c). A quality check is then performed and the thermoplastic substrate 200 with electronic components 220, 225 is rejected if it fails the check; see step 140.

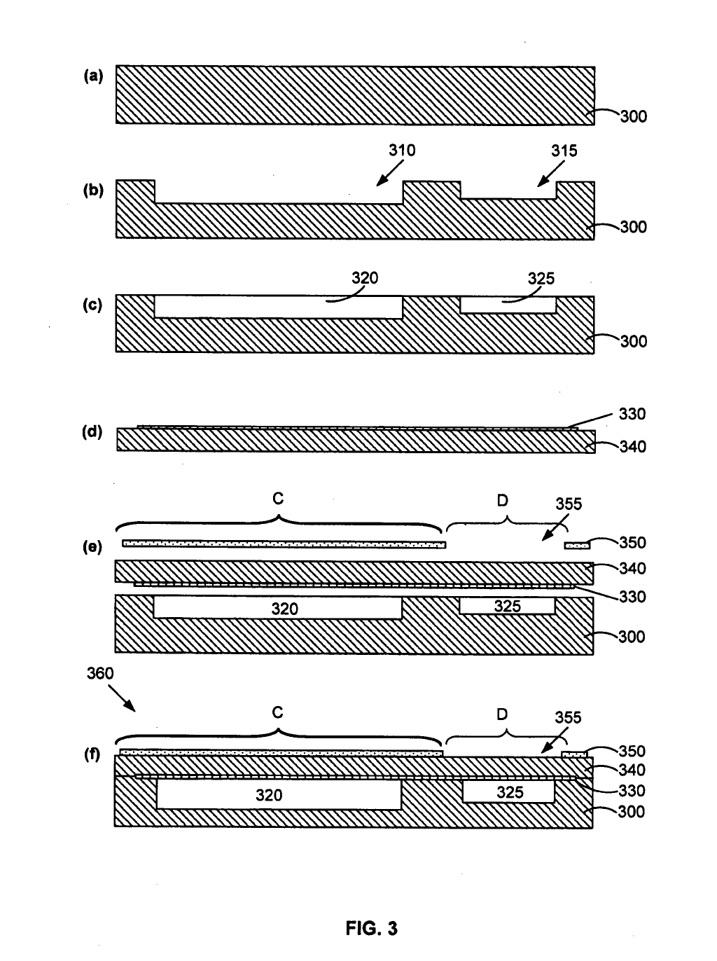

Following placement of the electronic components 220, 225, electrical circuitry 230 or conductive tracks are deposited. The electrical circuitry 230 may be deposited over the electronic components 220, 225; step 145 in FIG. 1 and FIG. 2(d). Alternatively, the electrical circuitry may be deposited onto a separate thermoplastic sheet 240; see step 150 in FIG. 1 and FIG. 3(d). In any event, a quality check is performed and the thermoplastic substrate 200 deposited with electrical circuitry is rejected if it fails the check; see step 155.

Any suitable methods such as screen printing and ink jet printing may be used for the deposition steps 145 and 150. Flexible conductive paste or ink may be used to form flexible electronic device when flexible thermoplastic material is used for the substrate 200 and sheet 240. Some components such as resistors, capacitors and sensing elements may also be printed during this stage of the process. A laser cut steel shim is used as a mask for the conductive ink.

Then in a thermal bonding process, the thermoplastic sheet 240 is then bonded with the thermoplastic substrate 200 to seal the electrical circuitry 230 and electronic components 220, 225 between the sheet 240 and substrate 200; see step 155 in FIG. 1. The thermoplastic sheet 240 is generally significantly thinner than the thermoplastic substrate 200, such as 0.1 mm, to serve as a laminate sheet.

A thermally conductive layer 250 is then bonded with the thermoplastic sheet 240 using heat and pressure; see step 170 in FIG. 1, FIG. 2(e) and FIG. 2(f). The thermally conductive layer 250 is used such that heat applied during the thermal bonding process is distributed more uniformly across regions of the thermoplastic sheet 240 overlaid by the thermally conductive layer 250. An adhesive backed aluminium foil may be used as the thermally conductive layer 250.

In the example shown in FIG. 2(f), the larger electronic component 220 such as a Computational Logic Unit (CPU) generally has a larger thermal mass than the smaller electronic component 225. The larger thermal mass disrupts the temperature profile across the thermoplastic sheet 240 and as such, without the thermally conductive layer 250, temperature distribution around the larger component 220 will be uneven, leaving adjacent region labelled ‘A’ to be hotter than distant region labelled ‘B’.

With the thermally conductive layer 250, heat applied during the thermal bonding process is distributed more uniformly across regions ‘A’ and ‘B’. Advantageously, the layer 250 allows heat flow and the bonding temperature of the thermoplastic sheet 240 to be relatively uniform, thereby improving bonding of the thermoplastic sheet 240 with the substrate 200 without significant plastic deformation in the vicinity of the large component 220 (region ‘A’).

During normal operation of the formed electronic device 260, the thermally conductive layer 250 has a second function of improving heat dissipation from the sealed electronic components 220, 225 and electrical circuitry 230 to the environment. Advantageously, the core temperature of the electronic device 260 during use is generally lower than in conventional circuit boards or electronic devices without the thermally conductive layer.

It should be understood that alternatively or in addition, the thermally conductive layer 250 may be bonded with the thermoplastic substrate 200 to achieve more uniform heat distribution during the thermal bonding process. Also, steps 160 and 170 in FIG. 1 can be combined such that the thermally conductive layer 250 is bonded with the thermoplastic sheet 240 in a single step. Alternatively, the thermally conductive layer 250 may be pre-bonded with the substrate 200 and/or sheet 240 prior to step 155 in FIG. 1.

Quality checks are performed in steps 165 and 170 and the formed electronic device 260 is rejected if it fails the check; see step 140.

Selective Thermal Distribution

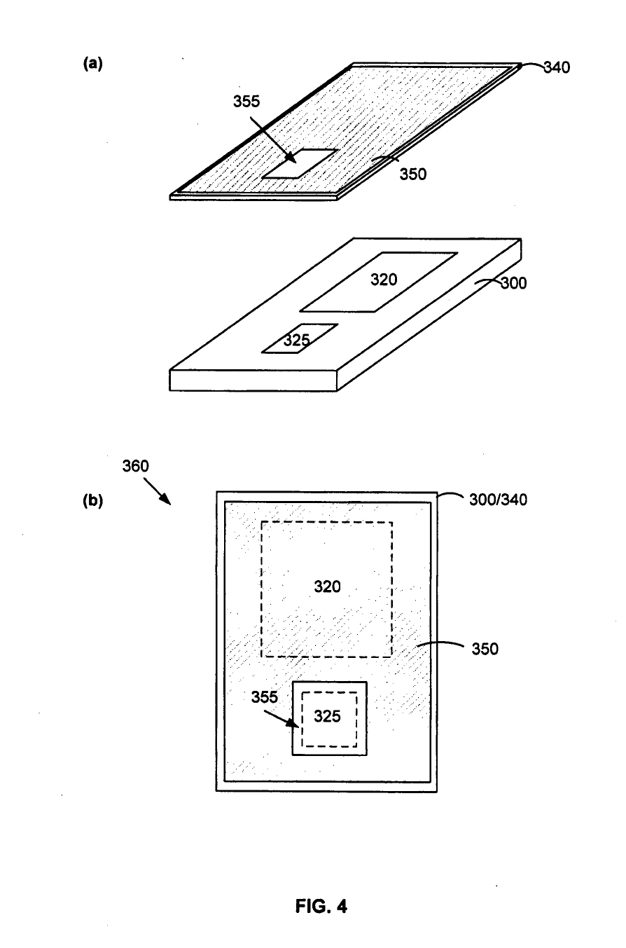

A second example of the thermally conductive layer will now be explained with reference to FIG. 3 and FIG. 4. Similarly, the electronic device 360 has a larger electronic component 320 in recess 310, a smaller electronic component 325 in recess 315 and electrical circuitry 330 sealed in thermoplastic substrate 300 and sheet 340. However, the smaller electronic component 325 is a heat-sensitive component that has a lower heat tolerance than the larger electronic component 320.

As shown in FIG. 3(e) and FIG. 3(f), the region around the heat-sensitive component 325 is labelled as ‘D’ while ‘C’ is the region around the larger component 320. During and after the thermal bonding process, region ‘C’ is of a higher temperature the larger thermal mass of the larger component 320. As such, although the method in FIG. 1 generally occurs at a much lower temperature than that of traditional soldering techniques, the heat-sensitive electronic component 325 may still be damaged during the thermal bonding process.

To reduce thermal flow from region ‘C’ to region ‘D’ to reduce heat exposure to the heat-sensitive component 325, the thermally conductive layer 350 is patterned in step 180 prior to step 170 in FIG. 1. Specifically, the thermally conductive layer 350 is formed with a cut-out hole 355 that overlies the heat-sensitive component 325 when the layer 350 is bonded with the thermoplastic sheet 240; see FIG. 3(e) and FIG. 3(f). The cut-out hole 355 can also be seen in partially exploded view in FIG. 4(a) and the top view in FIG. 4(b).

The patterned thermally conductive layer 350 reduces exposure of the heat-sensitive component 325 to the temperature fluctuations in region ‘C’. The rise in temperature of the heat-sensitive component 325 may be much less than that required for bonding and only the periphery of region ‘D’ will be bonded. In the process, the heat-sensitive component will still be sealed from the environment.

Similar to the first example, the patterned thermally conductive layer 350 also facilitates a more uniform heat distribution in region ‘C’, thereby improving bonding of the thermoplastic sheet 340 with the substrate 300 in this region. During normal operation of the electronic device 360, the patterned thermally conductive layer 350 facilitates selective thermal loss from the larger component 320 in region ‘C’. However, since region ‘D’ is not covered by layer 350, the heat-sensitive component 325 is less affected by temperature fluctuations of the layer 350 and region ‘C’. Such selectivity of thermal loss is important for system performance because the heat-sensitive component 325 only functions satisfactorily when operating at lower temperature.

Finally, it should be noted that although it is shown in FIG. 3(d) and FIG. 3(e) that the electrical circuitry 330 is deposited onto the thermoplastic sheet 340 according to step 150 in FIG. 1, it should be understood that the electrical circuitry 330 may also be deposited over the electronic components 320, 325.

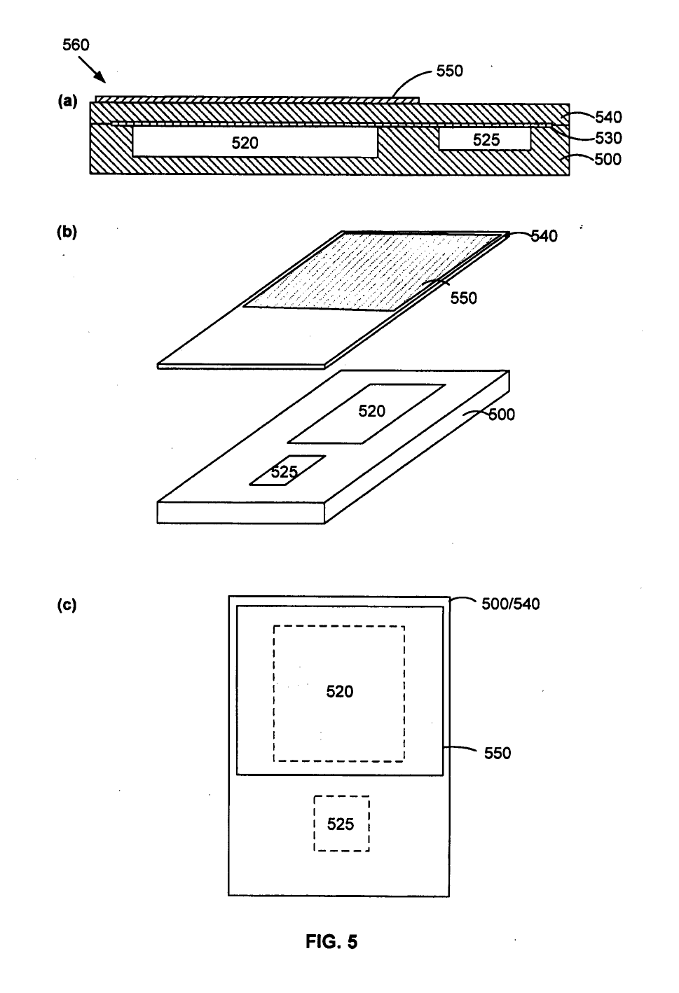

A third example of the thermally conductive layer 550 is shown in FIGS. 5(a), 5(b) and 5(c). Similarly, the electronic device 560 has a larger electronic component 520, a smaller electronic component 525 and electrical circuitry 530 sealed between a thermoplastic substrate 500 and thermoplastic sheet 540. However, instead of patterning the layer 550 to have a cut-out hole, the size of the layer 550 is reduced so as not to overlay the heat-sensitive component 325 to reduce thermal flow to the component 325 from the larger component 330.

Thermal Regulation

The thermally conductive layer 650 may be thermally drivable to regulate temperature of some or all parts of the electronic device 660 during its normal operation. Temperature regulation is important in applications where temperature of an electronic component needs to be strictly maintained within an operating range.

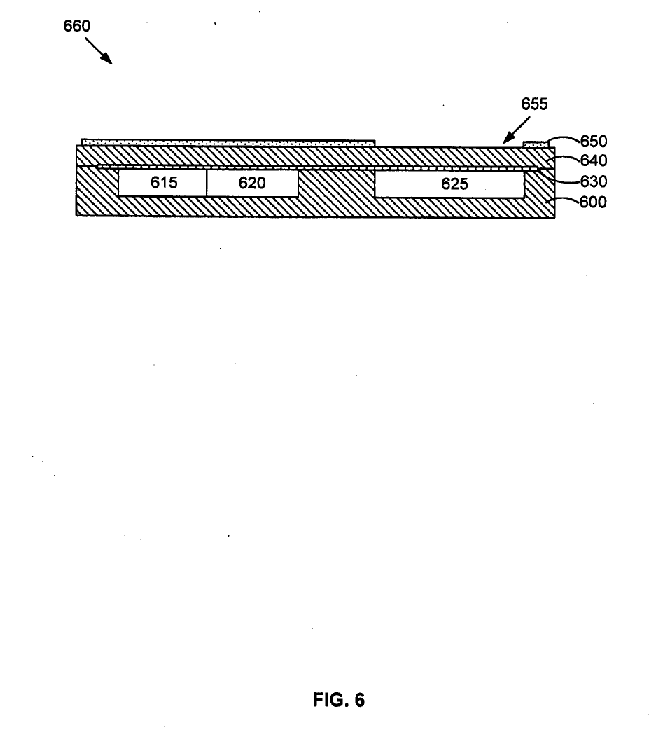

For example, FIG. 6 shows a fourth example of an electronic device 660 having a liquid crystal display (LCD) screen 625 sealed between the thermoplastic substrate 600 and 640. It is known that a LCD screen 625 fails to function satisfactory in both excessive heat and excessive cold. By surrounding the display with a thermally conductive layer 650 it is possible to use a temperature regulation pad 615 with a temperature sensor 620 to monitor the temperature of the LCD screen 625.

The temperature regulation pad 615 consists of a resistive heater (not shown), a peltier cooling device (not shown) and the nearby temperature sensor 620. The area of the pad 615 is designed to be sufficiently large to ensure sufficient thermal coupling between the pad 615 and the thermally conductive layer 650. The electrical connections between these components are part of the circuit connecting layer 630.

The temperature regulation pad 615 is positioned to be in close thermal contact with the thermally conductive layer 650. The temperature sensor 620 in the temperature regulation pad 615 provides feedback to the temperature control circuit so that the thermally conductive layer 650 is maintained within the operating range of the LCD display.

If the detected temperature exceeds a predetermined upper limit, then the peltier cooling device located in thermal contact with the thermally conductive layer 650 can be activated to reduce the temperature. Similarly, if detected temperature is below a predetermined lower limit, then the resistive heater coupled to the thermally conductive layer 650 can be activated to raise the temperature of the display. In this way, the temperature of the display can be maintained between the recommended operational limits.

In another example, printable voltage controlled visible display layers are known to operate in a relatively restricted temperature range and as such, the same thermo-regulation system as described with reference to FIG. 6 can be implemented here.

Other Applications

In other applications, the thermally conductive layer may also be patterned according to step 180 in FIG. 1 to serve as an electromagnetic shield, antenna and/or information display.

(a) Electromagnetic Shield

Electromagnetic compatibility is a major issue in electronics manufacture, and can be generally defined in two ways: the effect of radio emission from your product on other products, and the effect of the radiation of other products on your product. There are international regulations which specify how much unintentional radio energy can be emitted from a device. The conventional method of reducing radiated emissions is to enclose the device in a partial or full conducting (electric and/or magnetic) shield.

In some electronic devices, it is desirable to minimise the effect of nearby objects on the radio frequency characteristics of the circuitry. For example, in circuits and systems that incorporate a radio frequency transmitter, the radiation performance can be severely impaired by the presence of a nearby object. For example, the microwave power radiated from a cellular telephone is reduced if the user's hand, head or other object is located very close to the antenna. This effect can be minimised if the antenna is designed to radiate efficiently when located at a fixed distance from an electrically conductive ground plane.

In another application, the thermally conductive layer may also be electrically conductive and patterned to function as an electromagnetic shield to improve electromagnetic performance of the electronic device. For example, if there is a requirement to shield one or more sides of the electronic device, then the layer can be patterned to cover one or more sides of the electronic device. In this case, the layer also functions as a ground plane. An additional effect is that the radiation exposure of the user is reduced through the incorporation of the electromagnetic shield.

In relation to the second example in FIG. 3 and FIG. 4, it should be noted that electromagnetic shields designed for electromagnetic compatibility must be large in size compared to a free space wavelength. If the thermally and electrically conductive shield has a cut-out hole with dimensions less than 10% of one wavelength, the leakage of radiation through that hole is generally very small and the shield can be considered to be intact.

(b) Antenna

In a further application, the thermally conductive layer 750 may also be electrically conductive and patterned to function as an antenna, such as a resonant antenna to improve electromagnetic performance of the electronic device 760.

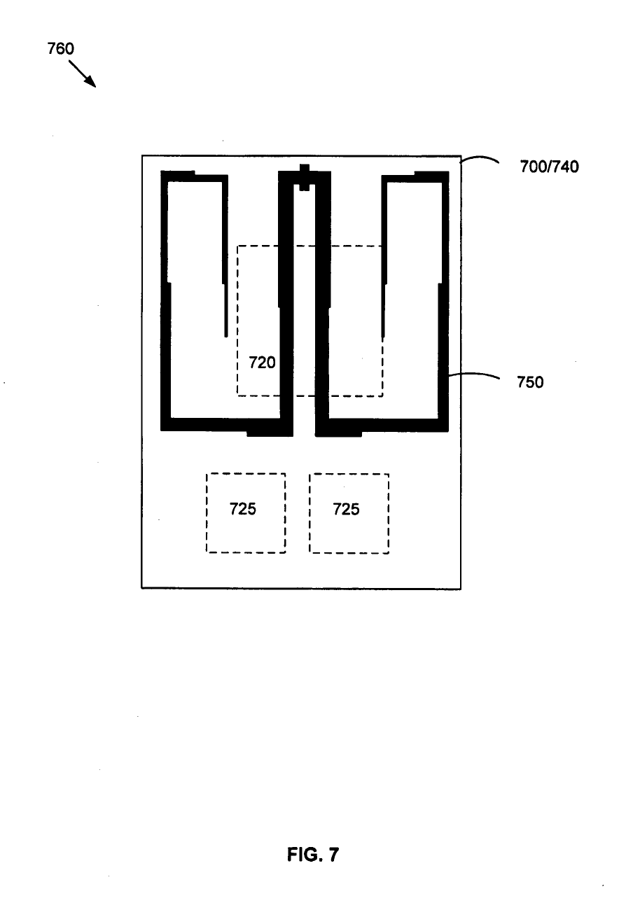

For example, as shown in FIG. 7, the layer 750 is patterned as a meander line dipole antenna that is inductively coupled to electronic component 720 sealed between the thermoplastic sheet 740 and substrate 700. The multipurpose layer in this case not only facilitates thermal distribution and loss, but also serves as an antenna. During the process of forming the electronic device 760, the thermally and electrically conductive layer 750 facilitates uniform thermal distribution in the vicinity of the sealed electronic component 720 while reducing heat exposure to other sealed heat-sensitive components 725. During normal use of the electronic device 700, the layer 750 serves as an antenna.

It will be appreciated that the antenna 710 may be of printed shapes of wires or patterned surface. Note that in most electronic systems using radio technology, most energy is consumed in the radio circuit.

(c) Information Display

The thermally conductive layer may also be patterned to display visual and textual information, such as a brand or information of the electronic device. The information may be printed onto the layer during step 180 shown in FIG. 1.

Other Advantages

The method, in one or more embodiments, offers a number of advantages. For example in some applications, the method reduces the cost of production and reduces energy requirements for manufacturing and disassembly. Since the electronic components and circuitry are sealed from the environment, they are protected from environmental degradation over time. Conventional circuitry design tools and screen printing techniques can be used.

The method is also lead-free and compliant with the Directive on the Restriction of the Use of Certain Hazardous Substances in Electrical and Electronic Equipment (2002/95/EC, ‘RoHS Directive’) and Directive on the Waste Electrical and Electronic Equipment (2002/96/EC, ‘WEEE Directive’). The amount of waste generated in the method is generally much less than that produced in the standard solder reflow system and the wet/dry etch PCB technology.

Further, the method also improves or simplifies recycling of the electronic device formed. Biodegradable or biocompatible thermoplastic material may be used. The thermoplastic sheet may be unsealed from the thermoplastic substrate to remove electronic components and circuitry for recycling. Similarly, the thermally conductive layer may be removed during this process.

The method is applicable to small electronic devices that need to have its components and electrical circuitry isolated from the environment. These devices are particularly suitable for low power applications with low heat loss such as sensors used in watering systems, sports data loggers, internal medical monitoring devices and microfluidic biological devices. For example, fluid channels may be formed during the hot embossing process. The electronic device may be formed in any shape. For example, three-dimensional curved edges are possible using external mould and custom designed jig during the embossing process in step 125.

Variations

Besides aluminium, the thermally conductive layer may be made of copper, silicon carbide, metal alloys, printed silver, printed carbon, and conductive polymers, polymer and ceramic composites.

Electrical conductive polymer, such as PEDOT:PSS, may also be used for the electrical circuitry. A layer of the polymer may be deposited using techniques such as spin coating and patterned to conform to a shape required of the electromagnetic shield or the antenna.

Although the examples have been shown to have a larger component and a smaller component, it should be understood that multiple of such components may be used and the thermally conductive layer may be patterned to control temperature of the components according to different circuit designs and applications.

Laser machining may be used to form recesses in the thermoplastic substrate. The deposition of the circuitry may be also be performed by adhering conductive tapes to the thermoplastic sheet or over the electrical components placed in the thermoplastic substrate.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

1. A method of forming an electronic device in plastic, comprising the steps of:
(a) placing electronic components in recesses in a thermoplastic substrate;
(b) depositing an electronic circuit over the electronic components, or onto a thermoplastic sheet; and
(c) bonding the thermoplastic substrate with the thermoplastic sheet in a thermal bonding process to seal the electronic components and the electronic circuit between the thermoplastic substrate and the thermoplastic sheet,
wherein the method further comprises providing a thermally conductive layer on the thermoplastic sheet and/or substrate such that heat applied during the thermal bonding process is distributed substantially uniformly across the thermoplastic sheet and/or substrate overlaid by the thermally conductive layer to facilitate bonding of the thermoplastic sheet and substrate.

2. The method of claim 1, wherein at least one of the electronic components is a heat-sensitive component and the method further comprises patterning the thermally conductive layer to reduce distribution of the heat applied during the thermal bonding process to the heat-sensitive component.

3. The method of claim 1, wherein the thermally conductive layer is thermally drivable with one or more of the sealed electronic components to regulate temperature to some or part of the electronic device.

4. The method of claim 1, further comprising bonding the thermally conductive layer to the thermoplastic sheet or substrate, or both, either during or before step (c).

5. The method of claim 1, wherein the layer is both thermally and electrically conductive.

6. The method of claim 5, further comprising patterning the thermally and electrically conductive layer to function as an electromagnetic shield for the sealed electronic components and electronic circuit.

7. The method of claim 5, wherein further comprising patterning the thermally and electrically conductive layer to function as an antenna that is inductively coupled to the sealed electronic circuit and/or one or more of the sealed electronic components.

8. The method of claim 1, further comprising patterning the layer to display textual or visual information.

9. The method of claim 1, wherein the layer comprises at least one of the following: aluminium foil, copper foil, printed silver, printed carbon, and conductive polymers.

10. An electronic device in plastic comprising a thermoplastic substrate, electronic components, a thermoplastic sheet and an electronic circuit, wherein:
(a) the electronic components are placed in recesses in thermoplastic substrate;
(b) the electronic circuit is deposited over the electronic components, or onto the thermoplastic sheet; and
(c) the thermoplastic substrate is bonded with the thermoplastic sheet in a thermal bonding process to seal the electronic components and the electronic circuit between the thermoplastic substrate and the thermoplastic sheet;
and wherein the electronic device further comprises a thermally conductive layer on the thermoplastic sheet and/or substrate such that heat applied during the thermal bonding process is distributed substantially uniformly across the thermoplastic sheet and/or substrate overlaid by the thermally conductive layer to facilitate bonding of the thermoplastic sheet and substrate.
